(19) United States
(12) Patent Application Publication
(10) Pub. No.: US 2008/0237734 A1
(43) Pub. Date: Oct. 2, 2008

(54) COMPLEMENTARY METAL-OXIDE-SEMICONDUCTOR TRANSISTOR AND METHOD OF FABRICATING THE SAME

(75) Inventors: Wen-Han Hung, Kaohsiung City (TW); Cheng-Tung Huang, Kaohsiung City (TW); Kun-Hsien Lee, Tainan City (TW); Shyh-Fann Ting, Kaohsiung County (TW); Li-Shian Jeng, Taitung City (TW); Meng-Yi Wu, Kaohsiung Hsien (TW); Chung-Min Shih, Tainan City (TW); Tzyy-Ming Cheng, Hsinchu (TW); Chia-Wen Liang, Hsinchu (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/693,470

(22) Filed: Mar. 29, 2007

(51) Int. Cl. H01L 29/76; H01L 21/8238

(52) U.S. Cl. 257/374; 438/221; 257/E29.226; 257/E21.632

(57) ABSTRACT

A complementary metal-oxide-semiconductor (CMOS) transistor comprising a substrate, a first conductive type MOS transistor, a second conductive type MOS transistor, a buffer layer, a first stress layer and a second stress layer is provided. The substrate has a device isolation structure therein that defines a first active area and a second active area. The first conductive type MOS transistor and the second conductive type MOS transistor are respectively disposed in the first active area and the second active area of the substrate. A first nitride spacer of the first conductive type MOS transistor has a thickness greater than that of a second nitride spacer of the second conductive type MOS transistor. The buffer layer is disposed on the first conductive type MOS transistor. The first stress layer is disposed on the buffer layer. The second stress layer is disposed on the second conductive type MOS transistor.

### BACKGROUND OF THE INVENTION

1. Field of the Invention

The present invention generally relates to an integrated circuit device and method of fabricating the same, and more particularly to a complementary metal-oxide-semiconductor (CMOS) transistor and a method of fabricating the same.

2. Description of Related Art

In the evolution of integrated circuit devices, high speed operation and low power consumption of the integrated circuit devices can be achieved by reducing its dimension. However, since the reduction in device dimension is currently limited by factors such as a bottleneck effect of the processing technique and a high fabrication cost. Therefore, techniques other than reducing the dimension of a device have to be developed in order to improve the driving current of the device.

As a result, the industry has developed a method that utilizes stain to enhance the performance of the device and break the barrier to device miniaturization. The aforementioned method includes forming a stress layer on the transistor device so as to produce strain in the channel region of the device and change the pitch of the silicon crystal lattice. Consequently, the mobility of the electrons or holes is enhanced and the driving current of the device is increased. Moreover, using the so-called ‘selective strain scheme’ (SSS) can increase the driving current of both P-type transistor and N-type transistor simultaneously. The selective strain scheme refers to the technique of forming a tensile silicon nitride layer capable of serving as a contact etching stop layer (CESL) on an N-type transistor so as to produce tensile strain in the channel region and increase electron mobility, and forming a compressive silicon nitride layer capable of serving as a CESL on a P-type transistor so as to produce compressive strain in the channel region and increase hole mobility.

For an integrated circuit device, electrical attributes are critical factors that determine the quality of the device. Although the selective strain scheme can increase the driving current of P-type and N-type transistors, increasing the integrity of devices or applying the selective strain scheme can hardly provide the electrical characteristics required by the device as new processing techniques continue to develop in the future. Consequently, how to provide integrated circuit devices with better electrical attributes is one of the goals in the industry.

In addition, the aforementioned and related techniques have been disclosed in a few U.S. Patents, for example, US 2006/0099763, U.S. Pat. No. 7,002,209 and US 2005/0266639. The foregoing patents are some of the reference materials in the present invention.

### SUMMARY OF THE INVENTION

Accordingly, the present invention is to provide a method of fabricating a complementary metal-oxide-semiconductor (CMOS) transistor that can resolve the problem of the conventional method of not being able to completely provide the required electrical attributes of a device by relying only on increasing the level of integration or applying the selective stress scheme, and significantly improve device performance by using a simpler process.

The present invention also provides a CMOS transistor having a significantly improved device performance over that of a convention device with a high level of integration or a selective stress scheme applied.

As embodied and broadly described herein, the invention provides a method of fabricating a complementary metal-oxide-semiconductor (CMOS) transistor. The method includes forming a device isolation structure in a substrate to define a first active area and a second active area in the substrate. Next, a first conductive type MOS transistor is formed on the first active area and a second conductive type MOS transistor is formed on the second active area simultaneously. The first conductive type MOS transistor includes a first gate structure formed on the substrate, a first doped region formed in the substrate on each side of the first gate structure, and a first nitride spacer formed on the sidewalls of the first gate structure and covering a portion of the first doped region. The second conductive type MOS transistor includes a second gate structure formed on the substrate, a second doped region formed in the substrate on each side of the second gate structure, and a second nitride spacer formed on the sidewalls of the second gate structure and covering a portion of the second doped region. Then, a buffer layer is formed over the substrate to cover the whole substrate. Thereafter, a first stress layer and a dielectric layer are sequentially formed on the buffer layer. Next, the dielectric layer, the first stress layer, the buffer layer and at least a portion of the second nitride spacers on the second active area are removed. After that, a second stress layer is formed over the substrate to conformally cover the whole substrate. Finally, the second stress layer in the first active area is removed.

According to the method of fabricating a CMOS transistor in the embodiment of the present invention, the method of removing the dielectric layer, the stress layer, the buffer layer and at least a portion of the second nitride spacers on the second active area is performing an etching process, for example. The foregoing etching process can be performed in an in-situ manner.

According to the method of fabricating a CMOS transistor in the embodiment of the present invention, the method of removing the second stress layer of the first active area is performing an etching process, for example.

According to the method of fabricating a CMOS transistor in the embodiment of the present invention, the first stress layer is a compressive stress layer and the second stress layer is a tensile stress layer when the first conductive type MOS transistor is a P-type MOS transistor and the second conductive type MOS transistor is an N-type MOS transistor.

According to the method of fabricating a CMOS transistor in the embodiment of the present invention, the material of the first and the second nitride spacers is silicon nitride, for example.

According to the method of fabricating a CMOS transistor in the embodiment of the present invention, the material of the first and the second stress layers is silicon nitride or silicon oxide, for example.

According to the method of fabricating a CMOS transistor in the embodiment of the present invention, the method of forming the first and the second stress layers is performing a chemical vapor deposition process, for example.

According to the method of fabricating a CMOS transistor in the embodiment of the present invention, the method may further include forming a first liner between the first gate structure and the first nitride spacer of the first conductive type MOS transistor, and forming a second liner between the second gate structure and the second nitride spacer of the second conductive type MOS transistor before forming the buffer layer. The material of the first and the second liners is silicon oxide, for example.

According to the method of fabricating a CMOS transistor in the embodiment of the present invention, the method further includes forming a first silicide layer on the surface of the first gate structure and the first doped region of the first conductive type MOS transistor, and forming a second silicide layer on the surface of the second gate structure and the second doped region of the second conductive type MOS transistor before forming the buffer layer.

The present invention also provides a complementary metal-oxide-semiconductor (CMOS) transistor. The CMOS transistor includes a substrate, a first conductive type MOS transistor, a second conductive type MOS transistor, a buffer layer, a first stress layer and a second stress layer. The substrate has a device isolation structure therein that defines a first active area and a second active area. The first conductive type MOS transistor is disposed in the first active area of the substrate. The first conductive type MOS transistor includes a first gate structure disposed on the substrate, a first doped region disposed in the substrate on each side of the first gate structure, and a first nitride spacer disposed on the sidewalls of the first gate structure and covering a portion of the first doped region. The second conductive type MOS transistor is disposed in the second active area of the substrate. The second conductive type MOS transistor includes a second gate structure disposed on the substrate, a second doped region disposed in the substrate on each side of the second gate structure, and a second nitride spacer disposed on the sidewalls of the second gate structure and covering a portion of the second doped region. The thickness of the first nitride spacer of the first conductive type MOS transistor is greater than that of the second nitride spacer of the second conductive type MOS transistor. The buffer layer is disposed conformally on the first conductive type MOS transistor. The first stress layer is disposed on the buffer layer. The second stress layer is disposed on the second conductive type MOS transistor.

According to the CMOS transistor in the embodiment of the present invention, the first stress layer is a compressive stress layer and the second stress layer is a tensile stress layer when the first conductive type MOS transistor is a P-type MOS transistor and the second conductive type MOS transistor is an N-type MOS transistor.

According to the CMOS transistor in the embodiment of the present invention, the material of the first and the second nitride spacers is silicon nitride, for example.

According to the CMOS transistor in the embodiment of the present invention, the material of the first and the second stress layers is silicon nitride or silicon oxide, for example.

According to the CMOS transistor in the embodiment of the present invention, the CMOS transistor further includes a first liner and a second liner. The first liner is disposed on the sidewalls of the first gate structure and the first doped region of the first conductive type MOS transistor. The second liner is disposed on the sidewalls of the second gate structure and the second doped region of the second conductive type MOS transistor.

According to the CMOS transistor in the embodiment of the present invention, the material of the first and the second liners is silicon oxide, for example.

According to the CMOS transistor in the embodiment of the present invention, the CMOS transistor further includes a first silicide layer and a second silicide layer. The first metal silicide layer is disposed on the surface of the first gate structure and the first doped region of the first conductive type MOS transistor. The second silicide layer is disposed on the surface of the second gate structure and the second doped region of the second conductive type MOS transistor.

In the process of removing the compressive stress layer above the N-type MOS transistor in the present invention, at least a portion of the nitride spacers is simultaneously removed so that the thickness of the nitride spacers is reduced. This method of reducing the thickness of the nitride spacers of the N-type MOS transistor can produce a greater stress in the channel of the N-type MOS transistor so as to increase its driving current gain (Iₒₙ gain). The present invention has already applied the selective strain scheme (SSS) to improve the performance of the P-type and the N-type MOS transistors. Therefore, with the additional application of the method of increasing the driving current gain of the N-type MOS transistor by reducing the thickness of the nitride spacers of the N-type MOS transistor, overall performance of the device is significantly improved. Furthermore, by controlling the timing of the etching process, the thickness of the nitride spacers of the N-type MOS transistor can be more accurately controlled. As a result, the desired device performance can be produced through processing adjustments. On the other hand, a portion of the nitride spacers can be removed, for example, by performing an in-situ etching process. Hence, simplicity in the processing can be maintained and fabrication cost can be reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1 through 7 are schematic cross-sectional views showing a method of fabricating a CMOS transistor according to an embodiment of the present invention.

FIG. 8 is a schematic cross-sectional view of a CMOS transistor according to another embodiment of the present invention.

FIG. 9 is a diagram plotting the relation between thickness of a nitride spacer of a P-type and an N-type MOS transistor and percentage gain of a driving current of the device.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

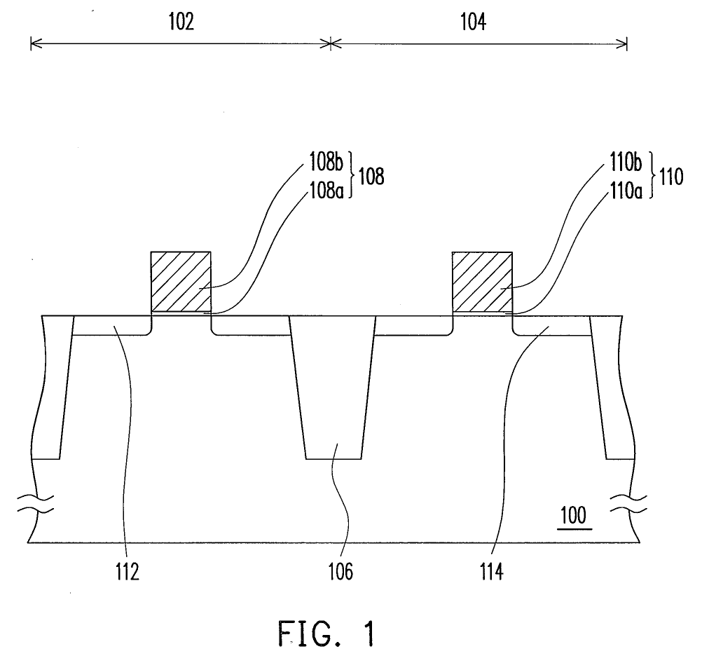

FIGS. 1 through 7 are schematic cross-sectional views showing a method of fabricating a CMOS transistor according to an embodiment of the present invention.

First, as shown in FIG. 1, a device isolation structure 106 is formed in a substrate 100 to define a first active area 102 and a second active area 104. The device isolation structure 106 is a shallow trench isolation (STI), for example. The method of forming the STI includes etching the substrate 100 to produce a trench and then filling the trench with a dielectric material, for example.

In the present embodiment, a P-type metal-oxide-semiconductor (MOS) transistor formed on the first active area 102 and an N-type metal-oxide-semiconductor (MOS) transistor formed on the second active area 103 are used as an example for a more detailed description below.

As shown in FIG. 1, a gate structure 108 is formed on the substrate 100 in the first active area 102 and a gate structure 110 is formed on the substrate 100 in the second active area 104. The gate structure 108 is composed of a gate dielectric layer 108a and a gate conductive layer 108b and the gate structure 110 is composed of a gate dielectric layer 110a and a gate conductive layer 110b, for example. The method of forming the gate structures 108 and 110 is, for example, forming a dielectric layer (not shown) on the substrate 100. The dielectric layer is normally formed in a high temperature oxidation process of the substrate 100. Next, a conductive layer (not shown) is formed on the dielectric layer. The conductive layer is, for example, a polysilicon layer formed in a chemical vapor deposition process. Thereafter, the conductive layer and the dielectric layer are defined to form the gate structures 108 and 110.

Next, an ion implant process is performed to form source/drain extensions (SDE) 112 and 114 in the substrate 100 on two sides of the gate structures 108 and 110.

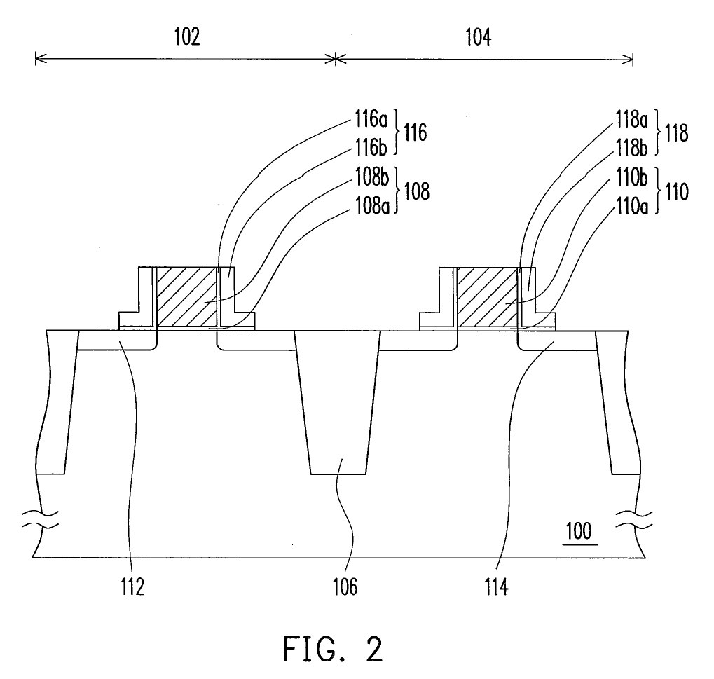

As shown in FIG. 2, spacers 116 and 118 are formed on the sidewalls of the gate structures 108 and 110 respectively. The spacer 116 is composed of an oxide liner 116a and a nitride spacer 116b, and the spacer 118 is composed of an oxide liner 118a and a nitride spacer 118b, for example. The method of forming the spacers 116 and 118 is, for example, sequentially forming a silicon oxide layer (not shown) and a silicon nitride layer (not shown) over the substrate 100 to conformally cover the gate structures 108, 110 and the source/drain extensions 112, 114. Thereafter, an etching technique is applied to etch the silicon nitride layer and the silicon oxide layer, so as to form the oxide liner 116a and the nitride spacer 116b on the sidewalls of the gate structure 108 and form the oxide liner 118a and the nitride spacer 118b on the sidewalls of the gate structure 110.

In other embodiments, offset spacers (not shown) may be formed between the gate structure 108 and the spacer 116 and between the gate structure 110 and the spacer 118. Each of the offset spacers is an oxide layer or a nitride layer, for example.

In FIG. 2, the nitride spacers 116b and 118b are drawn as L-shape structures. However, the nitride spacers 116b and 118b can have an arc-shape. In the present invention, there is no intention of limiting the shape of the spacers and the number of layers in the spacers.

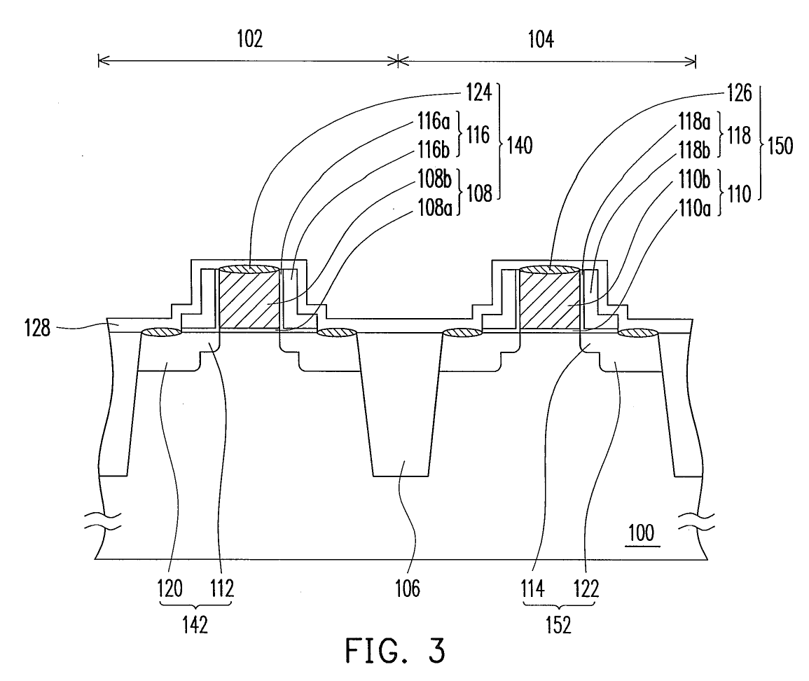

Next, as shown in FIG. 3, an ion implant process is performed to form source/drain 120 and 122 in the substrate 100 on the two sides of the gate structures 108 and 110.

Then, a silicide layer 124 is formed on the surface of the gate structure 108 and the exposed source/drain 120, and a silicide layer 126 is formed on the surface of the gate structure 110 and the exposed source/drain 122. The method of forming the silicide layers 124 and 126 is, for example, forming a metal layer (not shown) to conformally cover the whole substrate 100. The material of the metal layer is, for example, titanium (Ti), cobalt (Co), nickel (Ni) or other suitable metal material. Next, a thermal treatment of the metal layer is performed so that the metal layer reacts with a film layer in contact with the metal layer. The thermal treatment is a rapid thermal annealing process, for example. After that, an isotropic etching process is performed to remove the unreacted metal layer while retaining the silicide layers 124 and 126.

After forming the silicide layer 124, a P-type MOS transistor 140 is formed on the first active area 102 and an N-type MOS transistor 150 is formed on the second active area 104. The source/drain extension 112 and the source/drain 120 serve as a doped region 142 of the P-type MOS transistor. Similarly, the source/drain extension 114 and the source/drain 122 serve as a doped region 152 of the N-type MOS transistor 150.

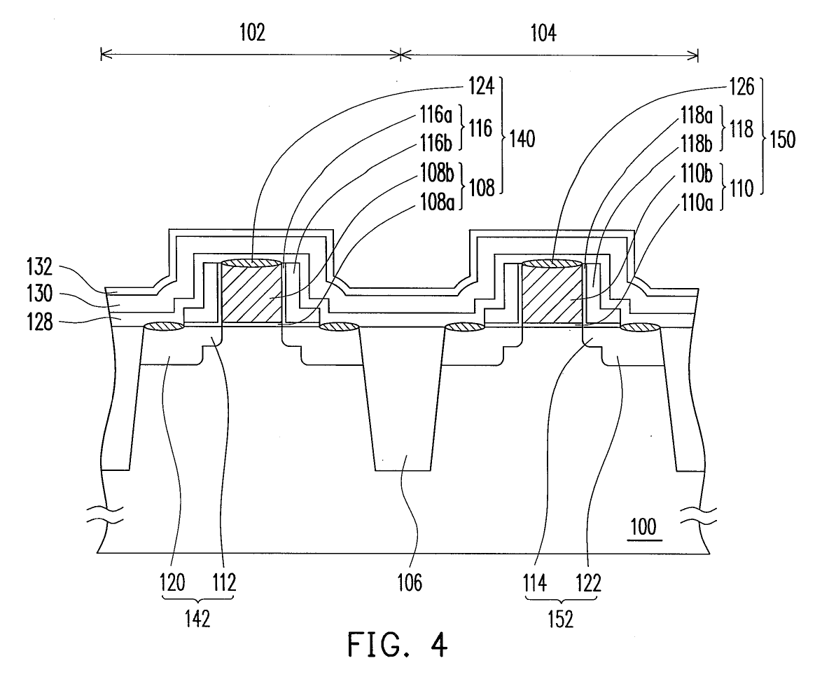

Thereafter, as shown in FIG. 4, a buffer layer 128 is formed conformally cover the whole substrate 100. The buffer layer 128 is an oxide layer fabricated, for example, using silicon oxide or other suitable material. The method of forming the buffer layer 128 is, for example, a chemical vapor deposition process or other suitable processes.

Next, a compressive stress layer 130 is formed on the buffer layer 128. The material of the compressive stress layer 130 is silicon nitride and the method of forming the compressive stress layer 130 is performing a low-pressure chemical vapor deposition process, for example. Obviously, the material of the compressive stress layer 130 can be silicon oxide, for example. Furthermore, the value of stress in the compressive stress layer 130 can be adjusted by performing a doping process or an annealing process. After forming the compressive stress layer 130, a dielectric layer 132 is formed on the compressive stress layer 130. The material of the dielectric layer 132 is silicon oxide or silicon nitride and the method of forming the dielectric layer 132 is performing a chemical vapor deposition process, for example.

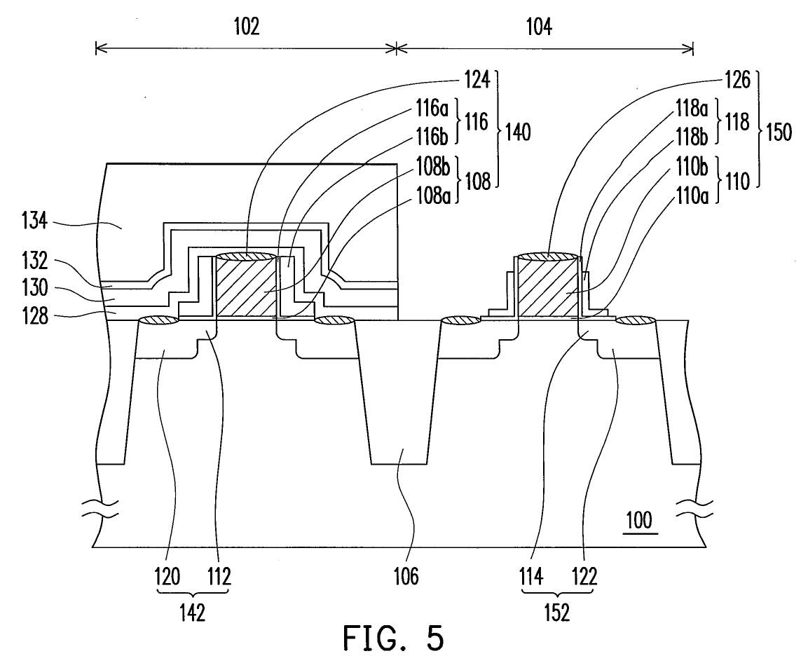

As shown in FIG. 5, a photoresist layer 134 is formed to cover the dielectric layer 132 in the first active area 102. Then, an etching process is performed using the photoresist layer 134 as a mask to remove the dielectric layer 132, the compressive stress layer 130, the buffer layer 128 and at least a portion of the nitride spacers 118b on the second active area 104. The foregoing etching process is an in-situ etching process, for example. More specifically, the various steps for removing the dielectric layer 132, the compressive stress layer 130, the buffer layer 128 and at least a portion of the nitride spacers 118b on the second active area 104 can be performed in the same reaction chamber or on the same processing machine, for example. As a result, simplicity of the process can be maintained and fabrication cost can be reduced.

It should be noted that the foregoing step of removing at least a portion of the nitride spacers 118b means that only a portion of each nitride spacer 118b is removed or the entire nitride spacer 118b is removed so as to reduce the thickness of the nitride spacers 118b. In FIG. 5, only a portion of each nitride spacer 118b is removed. Since those skilled in the art may understand what it is like after removing the nitride spacer 118b removed, a detailed drawing is omitted.

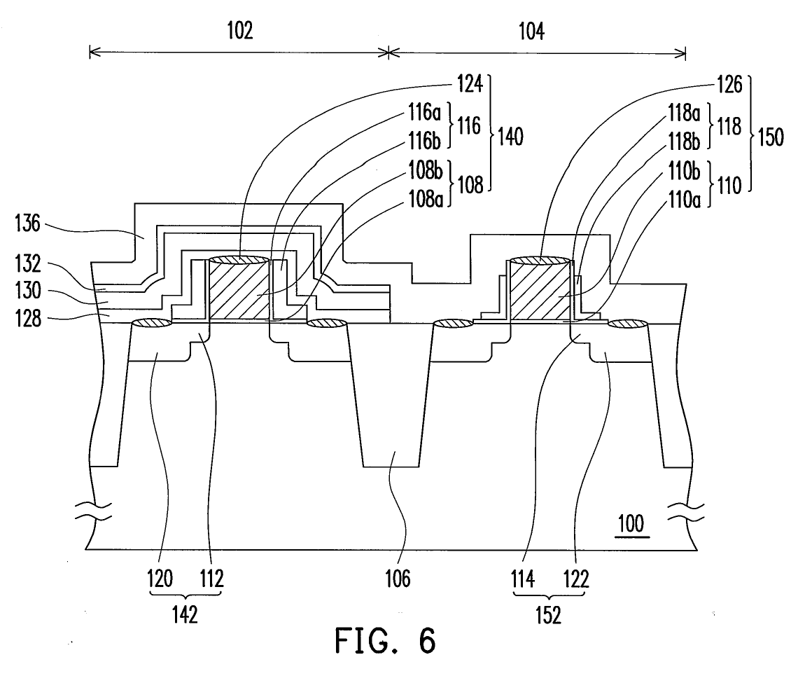

As shown in FIG. 6, a tensile stress layer 136 is formed over the substrate 100 so as to conformally cover the whole substrate 100. The material of the tensile stress layer 136 is silicon nitride and the method of forming the tensile stress layer 136 is performing a low-pressure chemical vapor deposition process, for example. Obviously, the material of the tensile stress layer 136 is silicon oxide, for example. In addition, the stress value can be adjusted by performing a doping process or an annealing process.

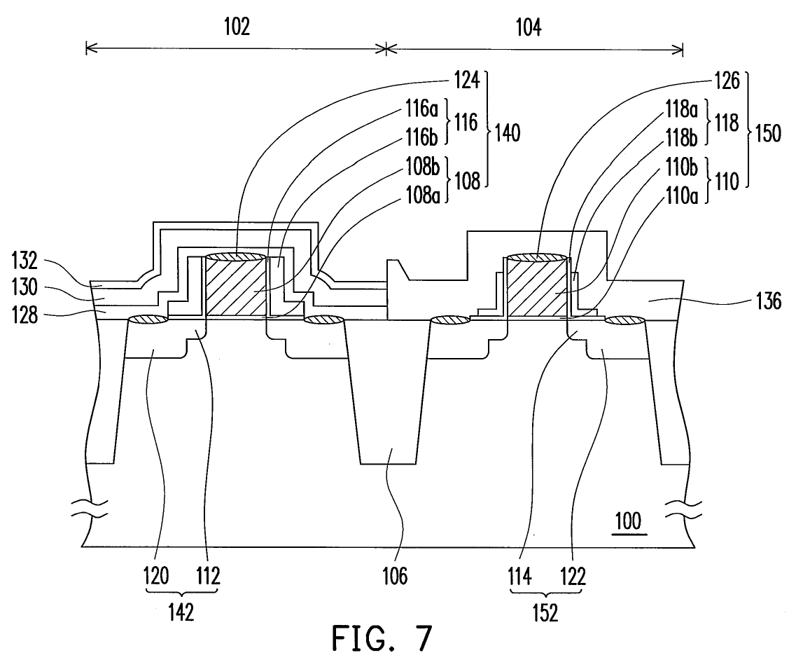

As shown in FIG. 7, the tensile stress layer 136 on the first active area 102 is removed while the tensile stress layer 136 on the second active area 104 is retained. The method of removing the tensile stress layer 136 on the first active area 102 is, for example, forming a photoresist layer (not shown) over the tensile stress layer 136 in the second active area 104 and performing an etching process using the photoresist layer as a mask.

It should be noted that at least a portion of the nitride spacers are also removed so as to reduce the thickness of the nitride spacer when the compressive stress layer above the N-type MOS transistor is removed in the foregoing embodiment. The method of reducing the thickness of the nitride spacers of the N-type MOS transistor in the present embodiment can produce a greater stress in the channel of the N-type MOS transistor and increase driving current gain (Iₒₙ gain) of devices.

In particular, the present invention not only applies the selective strain scheme (SSS) to improve the performance of the P-type and the N-type MOS transistors, but also produces a greater stress in the channel by reducing the thickness of the nitride spacers of the N-type MOS transistor. Consequently, the driving current gain of the N-type MOS transistor is increased and the overall performance of the device is significantly improved. Furthermore, by controlling the timing of the etching process, the thickness of the nitride spacers of the N-type MOS transistor can be more accurately controlled. As a result, the desired device performance can be produced through processing adjustments.

Next, FIG. 7 is used to describe in detail the structure of a CMOS transistor fabricated according to the method of the present invention. In the following, descriptions regarding the material and shape of each component are omitted.

As shown in FIG. 7, the complementary metal-oxide-semiconductor (CMOS) transistor includes a substrate 100, a P-type MOS transistor 140, an N-type MOS transistor 150, a buffer layer 128, a compressive stress layer 130 and a tensile stress layer 136. The substrate 100 has a device isolation structure 106 disposed therein that defines the substrate 100 into a first active area 102 and a second active area 104. The buffer layer 128 is disposed conformally on the P-type MOS transistor 140. The compressive stress layer 130 is disposed on the buffer layer 128 and the tensile stress layer 136 is disposed conformally on the N-type MOS transistor 150.

The P-type MOS transistor 140 of the CMOS transistor is disposed in the first active area 102. The P-type MOS transistor 140 mainly includes a gate structure 108, nitride spacers 116b and P-type doped regions 142. The gate structure 108 is composed of a gate dielectric layer 108a and a gate conductive layer 108b, for example. Each P-type doped region 142 is composed of a source/drain extension 112 and a source/drain 120, for example. In addition, an oxide liner 116a can be disposed on the sidewalls of the gate structure 108 and over the P-type doped regions 142. Furthermore, a silicide layer 124 can be disposed on the surface of the gate structure 108 and the exposed source/drain 120.

The N-type MOS transistor 150 of the CMOS transistor is disposed in the second active area 104. The N-type MOS transistor 150 mainly includes a gate structure 110, nitride spacers 118b and N-type doped regions 152. The gate structure 110 is composed of a gate dielectric layer 110a and a gate conductive layer 110b, for example. Each N-type doped region 152 is composed of a source/drain extension 114 and a source/drain 122, for example. In addition, an oxide liner 118a can be disposed on the sidewalls of the gate structure 110 and over the N-type doped regions 152. Furthermore, a silicide layer 126 can be disposed on the surface of the gate structure 110 and the exposed source/drain 122.

In another embodiment, offset spacers (not shown) can be disposed between the gate structure 108 and the spacer 116 and between the gate structure 110 and the spacer 118 respectively.

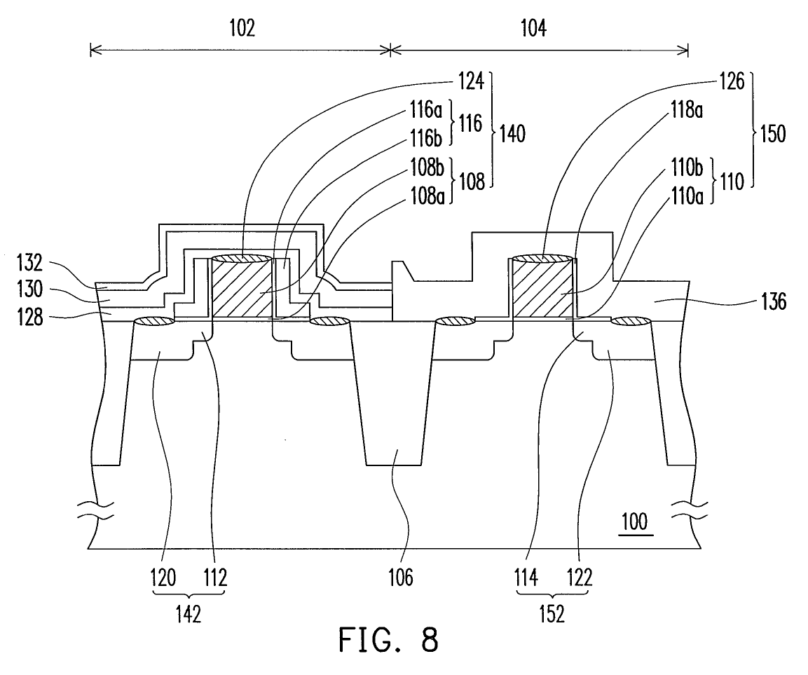

It should be noted that the thickness of the nitride spacers 116b of the P-type MOS transistor 140 in the present embodiment is greater than that of the nitride spacers 118b of the N-type MOS transistor 150. More specifically, as shown in FIG. 7, if the thickness of the nitride spacers 116b of the P-type MOS transistor is maintained at a process design standard thickness, then the thickness of the nitride spacers 118b of the N-type MOS transistor 150 is smaller than the process design standard thickness. Alternatively, if the thickness of the nitride spacers 116b of the P-type MOS transistor is maintained at the process design standard thickness, then no nitride spacer is disposed on the N-type MOS transistor 150 (as shown in FIG. 8).

Because the thickness of the nitride spacers of the P-type MOS transistor is maintained at the process design thickness while the nitride spacers of the N-type MOS transistor have a thickness smaller than that of the nitride spacers of the P-type MOS transistor, a greater stress is produced in the channel of the N-type MOS transistor so that the driving current gain of the NMOS transistor is increased.

In the present embodiment, the so-called selective strain scheme (SSS) is applied to improve the performance of the P-type and the N-type MOS transistors. In addition, the thickness of the nitride spacers of the N-type MOS transistor is made smaller than that of the nitride spacers of the P-type MOS transistor to enhance the performance of the N-type MOS transistor. Consequently, overall performance of the device is improved. Furthermore, by controlling the thickness of the nitride spacers of the N-type MOS transistor, the desired device performance can be produced through processing adjustments.

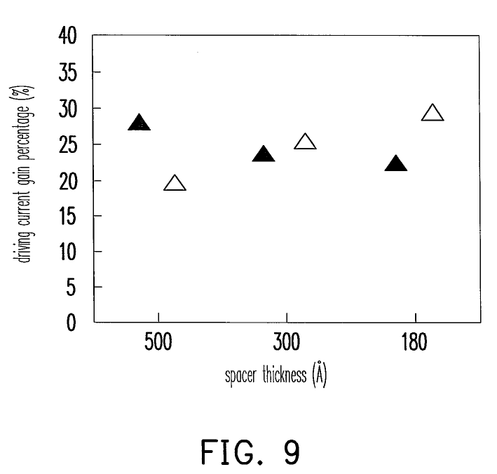

Next, FIG. 9 is used to show the capacity of the present invention for improving device performance.

FIG. 9 is a diagram showing the relation between thickness (Å) of the spacer of a P-type and an N-type MOS transistor with respect to the driving current gain percentage (%) of the device. As shown in FIG. 9, ▴ represents the measured driving current gain percentage of the device under different spacer thickness conditions when a compressive stress layer covers the P-type MOS transistor. Similarly, Δ represents the measured driving current gain percentage of the device under different spacer thickness conditions when a tensile stress layer covers the N-type MOS transistor. In FIG. 9, the electrical testing is performed under the conditions that the process design standard thickness of the spacers (including the oxide liner and the nitride spacer) of the MOS transistor is 500 Å and the thickness of the spacers is reduced to 300 Å and 180 Å respectively.

As shown in FIG. 9, reducing the thickness of the spacers of the P-type MOS transistor will lower its driving current gain. However, reducing the thickness of the spacers of the N-type MOS transistor will increase the driving current gain. Hence, the so-called selective stress scheme can be applied to the present invention to improve the performance of the P-type and the N-type MOS transistor simultaneously. Moreover, overall performance of the device can be further improved by reducing the thickness of the nitride spacers of the N-type MOS transistor Additionally, by controlling the thickness of the nitride spacers of the N-type MOS transistor, the desired device performance can be produced through processing adjustments.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a complementary metal-oxide-semiconductor (CMOS) transistor, comprising:
forming a device isolation structure in a substrate to define a first active area and a second active area;
forming a first conductive type metal-oxide-semiconductor (MOS) transistor on the substrate in the first active area and forming a second conductive type MOS transistor on the substrate in the second active area simultaneously,
wherein the first conductive type MOS transistor comprises a first gate structure formed on the substrate, a first doped region formed in the substrate on two sides of the first gate structure, and a first nitride spacer formed on the sidewalls of the first gate structure and covering a portion of the first doped region,
the second conductive type MOS transistor comprises a second gate structure formed on the substrate, a second doped region formed in the substrate on two sides of the second gate structure, and a second nitride spacer formed on the sidewalls of the second gate structure and covering a portion of the second doped region;
forming a buffer layer over the substrate to cover the whole substrate;
forming a first stress layer and a dielectric layer in sequence on the buffer layer;
removing the dielectric layer, the first stress layer, the buffer layer and at least a portion of the second nitride spacers in the second active area;
forming a second stress layer on the substrate to conformally cover the whole substrate; and
removing the second stress layer in the first active area.

2. The method of fabricating the CMOS transistor as claimed in claim 1, wherein the method of removing the dielectric layer, the first stress layer, the buffer layer and at least a portion of the second nitride spacers in the second active area comprises performing an etching process.

3. The method of fabricating the CMOS transistor as claimed in claim 2, wherein the etching process comprises performing in an in-situ manner.

4. The method of fabricating the CMOS transistor as claimed in claim 1, wherein the method of removing the second stress layer in the first active area comprises performing an etching process.

5. The method of fabricating the CMOS transistor as claimed in claim 1, wherein the first stress layer is a compressive stress layer and the second stress layer is a tensile stress layer as the first conductive type MOS transistor is a P-type MOS transistor and the second conductive type MOS transistor is an N-type MOS transistor.

6. The method of fabricating the CMOS transistor as claimed in claim 1, wherein a material of the first and the second nitride spacers comprises silicon nitride.

7. The method of fabricating the CMOS transistor as claimed in claim 1, wherein a material of the first and the second stress layers comprises silicon nitride or silicon oxide.

8. The method of fabricating the CMOS transistor as claimed in claim 1, wherein the method of forming the first and the second stress layers comprises performing a chemical vapor deposition process.

9. The method of fabricating the CMOS transistor as claimed in claim 1, wherein, before forming the buffer layer, farther comprising forming a first liner between the first gate structure and the first nitride spacer of the first conductive type MOS transistor, and forming a second liner between the second gate structure and the second nitride spacer of the second conductive type MOS transistor.

10. The method of fabricating the CMOS transistor as claimed in claim 9, wherein a material of the first and the second liners comprises silicon oxide.

11. The method of fabricating the CMOS transistor as claimed in claim 1, wherein, before forming the buffer layer, further comprising forming a first silicide layer on the surface of the first gate structure and the first doped region of the first conductive type MOS transistor, and forming a second silicide layer on the surface of the second gate structure and the second doped region of the second conductive type MOS transistor.

12. A complementary metal-oxide-semiconductor (CMOS) transistor, comprising:
a substrate has a device isolation structure defining the substrate into a first active area and a second active area;
a first conductive type MOS transistor, disposed on the substrate in the first active area, wherein the first conductive type MOS transistor comprises a first gate structure disposed on the substrate, a first doped region disposed in the substrate on two sides of the first gate structure, and a first nitride spacer disposed on the sidewalls of the first gate structure and covering a portion of the first doped region;
a second conductive type MOS transistor, disposed on the substrate in the second active area, wherein the second conductive type MOS transistor comprises a second gate structure disposed on the substrate, a second doped region disposed in the substrate on two sides of the second gate structure, and a second nitride spacer disposed on the sidewalls of the second gate structure and covering a portion of the second doped region
wherein the thickness of the first nitride spacer is greater than that of the second nitride spacer;
a buffer layer, disposed conformally on the first conductive type MOS transistor;
a first stress layer, disposed on the buffer layer; and
a second stress layer, disposed on the second conductive type MOS transistor.

13. The CMOS transistor as claimed in claim 12, wherein the first stress layer is a compressive stress layer and the second stress layer is a tensile stress layer when the first conductive type MOS transistor is a P-type MOS transistor and the second conductive type MOS transistor is an N-type MOS transistor.

14. The CMOS transistor as claimed in claim 12, wherein a material of the first and the second nitride spacers comprises silicon nitride.

15. The CMOS transistor as claimed in claim 12, wherein a material of the first and the second stress layers comprises silicon nitride or silicon oxide.

16. The CMOS transistor as claimed in claim 12, further comprising a first liner disposed on the sidewalls of the first gate structure and the first doped region of the first conductive type MOS transistor, and a second liner disposed on the sidewalls of the second gate structure and the second doped region of the second conductive type MOS transistor.

17. The CMOS transistor as claimed in claim 16, wherein a material of the first and the second liners comprises silicon oxide.

18. The CMOS transistor as claimed in claim 12, further comprising a first silicide layer disposed on the surface of the first gate structure transistor and the first doped region of the first conductive type MOS, and a second silicide layer disposed on the surface of the second gate structure and the second doped region of the second conductive type MOS transistor.
